(19) United States
(12) Patent Application Publication
(10) Pub. No.: US 2014/0220919 A1
(43) Pub. Date: Aug. 7, 2014

(54) AUTOMATIC FREQUENCY CONTROL METHODS AND APPARATUS

(71) Applicants: Jun Yang, Chengdu (CN); Yadunandana N Rao, Sunrise, FL (US); Jing Wang, Chengdu (CN); San-Shan Wang, Cheng Du (CN); Li Xiao, Chengdu (CN)

(72) Inventors: Jun Yang, Chengdu (CN); Yadunandana N Rao, Sunrise, FL (US); Jing Wang, Chengdu (CN); San-Shan Wang, Cheng Du (CN); Li Xiao, Chengdu (CN)

(21) Appl. No.: 14/347,914

(22) PCT Filed: Sep. 30, 2011
(86) PCT No.: PCT/CN2011/080481

§ 371 Date: Mar. 27, 2014

(51) Int. Cl. H03J 7/02; H04B 1/16

(52) U.S. Cl. CPC H03J 7/02; H04B 1/16
USPC 455/192.2

(57) ABSTRACT

Embodiments include Direct-Conversion Receiver (DCR) apparatus, and methods for performing automatic frequency control based on a received signal. An initial frequency offset value is selected from a lookup table and applied to the receiver's local oscillator. Digital samples are generated based on the received signal, and stored in a buffer in sequential order. A DC estimator performs multiple iterations of a DC component estimation process. The process includes iteratively applying an analysis window to more recently-stored, buffered samples, in order to identify a set of the buffered samples. Within the set of buffered samples, an intermediate value between the amplitudes of two samples is determined (e.g., samples having the largest and smallest amplitudes). Between at least some of the multiple iterations, the number of samples that defines the size of the analysis window is increased.

### FIELD OF THE DISCLOSURE

The present disclosure relates generally to automatic frequency control methods and apparatus in direct-conversion, radio frequency (RF) receivers, and more particularly to methods and apparatus that perform automatic frequency control based on estimates of direct current (DC) errors in a demodulated signal.

### BACKGROUND

A Direct-Conversion Receiver (DCR) demodulates an incoming radio signal using synchronous detection, which is driven by a local oscillator (LO) at the receiver. The incoming signals are directly down-converted to baseband signals by a quadrature mixer, with the LO frequency very close to the carrier frequency of the incoming signal.

One of the key issues with DCR architectures is the presence of DC errors in the baseband signals. The DC errors can lead to audio artifacts in analog FM radios, and can cause higher bit error rates in radios that use digital modulation. Further, in many scenarios, the DC errors will produce spurious, undesirable, audible tones when the frequency error between the transmitter and receiver falls within a certain range. This DC error can not be easily measured or removed when the baseband signal itself contains DC components, which is true for certain types of modulation (e.g., FM modulation with Digital Private Line (DPL) signaling). Accurately and rapidly controlling the frequency offset between the receiver's LO and the incoming signal carrier is a key to designing high performance DCRs.

Over the years, automatic frequency control (AFC) methods and apparatus have been implemented in FM receivers, in order to attempt to automatically control a receiver's LO frequency to a desired frequency corresponding to the carrier frequency of an incoming radio signal. Two measures of the performance of an AFC system are its characteristic convergence time and its frequency control error. The convergence time pertains to the amount of time that an AFC system requires, at the beginning of a transmission (e.g., at the beginning of a call), to reduce a frequency offset to an acceptable (e.g., pre-determined) level. The frequency control error pertains to the frequency offset that may remain, even after an AFC system has implemented its frequency offset reduction processes.

Generally, DCR designers attempt to design AFC systems with very short convergence times and very small frequency control errors. However, it is becoming increasingly more difficult for conventional AFC methods and apparatus to meet more stringent receiver design requirements with respect to convergence times and frequency control errors. Accordingly, there is a need for AFC methods and apparatus that are capable of meeting increasingly stringent receiver design requirements (i.e., AFC methods and apparatus characterized by shorter convergence times and/or smaller frequency control errors when compared with conventional AFC methods and apparatus).

### BRIEF DESCRIPTION OF THE FIGURES

The accompanying figures, where like reference numerals refer to identical or functionally similar elements throughout the separate views, together with the detailed description below, are incorporated in and form part of the specification, and serve to further illustrate embodiments of concepts that include the claimed invention, and explain various principles and advantages of those embodiments.

FIG. 1 is simplified block diagram of the front end of an FM receiver, in accordance with some embodiments.

FIG. 2 is a simplified block diagram of a DC estimator of an automatic frequency control (AFC) subsystem of an FM receiver, in accordance with some embodiments.

FIG. 3 is a table illustrating how time-varying sample selection windows are applied to incoming baseband samples, in accordance with some embodiments.

FIG. 4 is a chart illustrating time-varying sample selection windows, in accordance with some embodiments.

FIG. 5 is a graph plotting window size with respect to a number of buffered samples, in accordance with some embodiments.

FIG. 6 is a flowchart of a method of performing automatic frequency control, in accordance with some embodiments.

FIG. 7 is a graph plotting estimated frequency offsets with respect to time, and comparing the performance of AFC apparatus and methods, in accordance with various embodiments, with techniques for performing AFC that do not include the combination of apparatus and methods employed using the various embodiments.

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

The apparatus and method components have been represented where appropriate by conventional symbols in the drawings, showing only those specific details that are pertinent to understanding the embodiments of the present invention so as not to obscure the disclosure with details that will be readily apparent to those of ordinary skill in the art having the benefit of the description herein.

### DETAILED DESCRIPTION

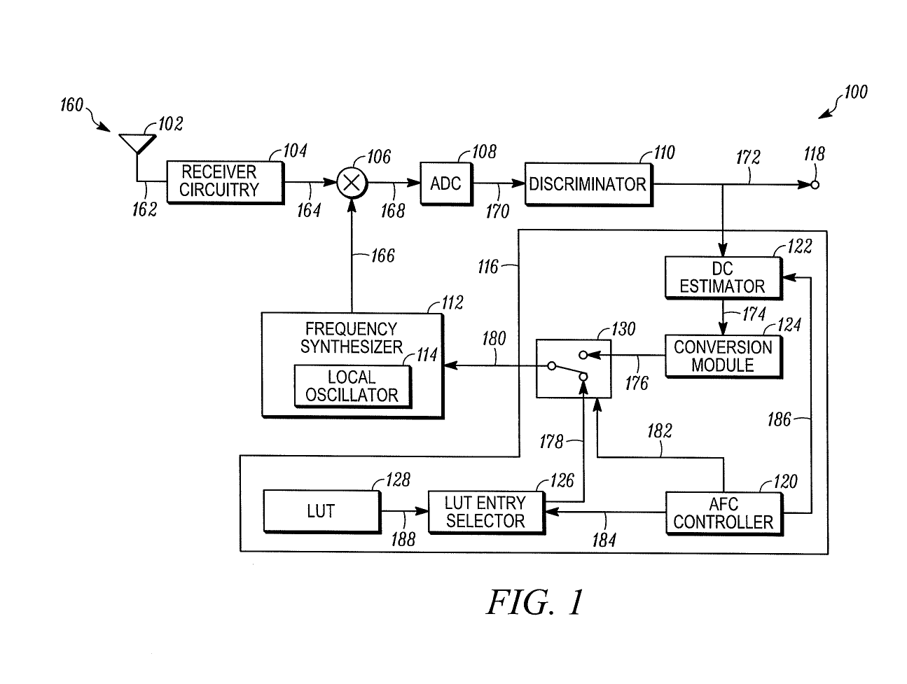

Embodiments of automatic frequency control (AFC) methods and apparatus disclosed herein may be capable of meeting more stringent receiver design requirements than conventional AFC methods and apparatus. For example, embodiments of AFC methods and apparatus disclosed herein may be characterized by significantly shorter convergence times and/or smaller frequency control errors when compared with such conventional AFC methods and apparatus. As will be explained in more detail below, embodiments include setting a desired frequency offset between a receiver's local oscillator (e.g., local oscillator 114, FIG. 1) and the carrier frequency of an incoming signal, so that there are very few DC components contained by the baseband signal itself. In various embodiments, by controlling the receiver's local oscillator frequency to a desired frequency offset from the carrier frequency, DC errors in the baseband signal may be removed effectively.

An embodiment of a method for performing automatic frequency control based on a received signal characterized by a DC component includes storing digital samples generated based on the received input signal in a buffer in a sequential order, resulting in a plurality of buffered samples, and performing multiple iterations of a first DC component estimation processes. The first DC component estimation process includes iteratively applying an analysis window to more recently stored ones of the buffered samples in order to identify a set of the buffered samples, wherein the analysis window has a variable window size, then within the set of buffered samples, determining an intermediate value between a first amplitude of a first sample and a second amplitude of a second sample, and between at least some of the multiple iterations, increasing a number of samples that defines the variable window size of the analysis window.

An embodiment of a method for controlling a local oscillator of an RF receiver in conjunction with performing automatic frequency control includes down-converting an RF signal received from a remote device using a local oscillator signal produced by the local oscillator, demodulating and processing the down-converted RF signal to produce a plurality of buffered samples, and as the plurality of buffered samples are produced, performing an iterative process. The iterative process includes performing multiple iterations of selecting a set of more recently produced ones of the buffered samples, wherein the set includes buffered samples that are encompassed by an analysis window with a window size that increases between at least some of the multiple iterations, and determining an intermediate value between a first amplitude of a first sample of the set and a second amplitude of a second sample of the set. The multiple iterations result in a plurality of intermediate values determined using differently sized analysis windows. The method also includes producing at least one of the intermediate values as an estimate of a DC component of the RF signal, and adjusting a frequency of the local oscillator signal based on the estimate of the DC component.

An embodiment of an automatic frequency control system of a receiver includes a buffer and a DC estimator. The buffer is configured to store buffered samples in a sequential order, where the buffered samples represent a received signal. The DC estimator is configured to perform multiple iterations of a first DC component estimation processes using the buffered samples. This includes iteratively identifying a set of the buffered samples that falls within an analysis window when the analysis window is applied to more recently stored ones of the buffered samples, where the analysis window has a variable window size, then within the set of buffered samples, determining an intermediate value between a first amplitude of a first sample and a second amplitude of a second sample, and when a window size increase trigger occurs, increasing a number of samples that defines the variable window size of the analysis window.

An embodiment of a direct conversion receiver system includes a lookup table, a lookup table entry selector, a DC estimator, and a controller. The lookup table includes a plurality of frequency offset values, where each of the plurality of frequency offset values corresponds to a possible frequency offset between a local oscillator of the receiver system and a carrier frequency onto which information within an incoming signal is modulated, where the possible frequency offset is within a desired frequency offset range within which the receiver system should operate. The lookup table entry selector is configured to select an initial frequency offset value from the lookup table at a first time, where the initial frequency offset value is applied to the local oscillator. The DC estimator is dynamically configurable to produce DC estimates of a DC component in a down-converted and digitized representation of the incoming signal, which is represented as a plurality of baseband samples. The controller is configured to determine when to adjust the local oscillator using the DC estimates by the DC estimator.

FIG. 1 is a simplified block diagram of the front end 100 of an FM receiver, in accordance with some embodiments. According to an embodiment, the receiver is a direct-conversion receiver (DCR), which demodulates an incoming RF, information-bearing signal (i.e., an RF signal 160 received via antenna 102) using a mixer 106 and a discriminator 110. The mixer 106 mixes the received RF signal 164 with a synthesized frequency signal 166, according to embodiments that will be discussed in more detail, below. Desirably, frequency synthesizer 112 produces synthesized frequency signal 166 at a frequency that is as close as possible to a frequency having a desired offset from the carrier frequency of an incoming signal 160 to which a remote device (i.e., a transmitter (not shown) of signal 160) up-converted a baseband or intermediate frequency, information-bearing signal prior to transmission. In contrast with superheterodyne receivers, the front end 100 of the DCR receiver converts signal 160 directly to baseband, rather than performing a multiple stage frequency down-conversion from an RF frequency to an intermediate frequency, and then from the intermediate frequency to baseband.

Receiver front end 100 includes an antenna 102, receiver circuitry 104, down-converting mixer 106, analog-to-digital converter (ADC) 108, discriminator 110, frequency synthesizer 112 (with local oscillator 114), and AFC sub-system 116, in an embodiment. Antenna 102 converts RF signal 160 from electromagnetic energy conveyed over the air interface into an analog signal 162 that is capable of being processed by receiver front end 100. The analog signal 162 produced by antenna 102 includes baseband information (e.g., baseband audio samples) modulated onto a carrier wave (at a carrier frequency) applied by the remote device. Receiver circuitry 104 receives analog signal 162, and performs several operations thereon, which typically include various filtering, amplification, and other processing operations, in order to produce a pre-processed, analog signal 164, which is provided to down-converting mixer 106. The signal 164 provided to down-converting mixer 106 also is conveyed at the carrier frequency.

Down-converting mixer 106 converts the frequency of analog signal 164 from RF to baseband, according to an embodiment, in order to produce an information-bearing, analog, baseband signal 168. This is accomplished by down-converting analog signal 164 (at the carrier frequency) using the synthesized frequency signal 166 from frequency synthesizer 112.

Frequency synthesizer 112 may include, for example, a Direct Digital Synthesizer (DDS), a Phase-Locked Loop (PLL) synthesizer, or another type of frequency synthesizer that includes at least one controllable local oscillator 114. As will be discussed in detail below, the frequency of synthesized frequency signal 166 corresponds to a signal produced by the local oscillator 114 based on a synthesizer control signal 180 from AFC subsystem 116. As will also be discussed in detail below, AFC subsystem 116 produces the synthesizer control signal 180 in a manner that enables the frequency signal 166 to converge quickly toward the carrier frequency (with the desired offset) that was produced at the remote transmitting device in conjunction with the remote transmitting device having up-converted, prior to transmission, the signal received as incoming RF signal 160.

ADC 108 receives the analog baseband signal 168 from down-converting mixer 106, and converts the signal 168 into a series of digital, modulated samples 170. According to an embodiment, ADC 108 produces the modulated samples 170 in quadrature form. More particularly, the modulated samples 170 include both in-phase (I) and quadrature (Q) samples that are 90 degrees out of phase from each other. The I and Q samples are subsequently processed by discriminator 110 in parallel processing channels, in an embodiment. For purposes of simplicity, however, only a single processing channel is depicted in FIG. 1.

Discriminator 110 receives the modulated samples 170 from ADC 108, and demodulates the modulated samples 170 to produce demodulated baseband samples 172 (referred to simply as “baseband samples,” below) at a sampling rate that is appropriate for the type of information conveyed in the incoming signal 160. For example, when the information conveyed in the incoming signal 160 corresponds to audio samples (e.g., voice samples), the sampling rate may pertain to the audio band, taking into account Nyquist criterion (e.g., between about 20 kilosamples/second (ks/s) and about 30 ks/s, although the sampling rate could be lower or higher, as well). For purposes of example only, descriptions of the various embodiments will assume a 20 ks/s sampling rate, which corresponds to an oversampled audio signal. It is to be understood that the sampling rate could be lower or higher, as well.

Baseband samples 172 are provided via output 118 to a baseband processing system (not illustrated), such as a digital signal processor (DSP) of the receiver. Processing that may be performed by such a processing system is outside the scope of the present disclosure, and will not be discussed herein. Baseband samples 172 also are provided to AFC subsystem 116, which is configured to provide synthesizer control signal 180 to frequency synthesizer 112, as discussed briefly above, in accordance with various embodiments.

Synthesizer control signal 180 indicates a frequency offset to frequency synthesizer 112. In an embodiment, synthesizer control signal 180 includes an actual frequency offset value, which represents a difference (or offset) between the frequency of the signal produced by local oscillator 114 and the carrier frequency applied to the incoming signal 160. As will be explained in more detail below, the frequency offset may either be selected (e.g., by lookup table (LUT) entry selector 126 from LUT 128) or estimated (e.g., by DC estimator 122 and conversion module 124). In an alternate embodiment, synthesizer control signal 180 may convey the frequency offset in some other manner (e.g., as a DC value or estimate), and frequency synthesizer 112 may convert the synthesizer control signal 180 into a value representing a frequency offset.

Either way, when a non-zero or non-negligible frequency offset is represented in the synthesizer control signal 180, frequency synthesizer 112 causes local oscillator 114 either to increase or decrease the frequency of the signal produced by local oscillator 114. This results in an increase or decrease in the frequency of the synthesized frequency signal 166 produced by frequency synthesizer 112. Desirably, the increase or decrease in the frequency of the synthesized frequency signal 166 is in a direction toward a frequency with a desired offset from the carrier frequency applied to the incoming signal 160. In other words, the increase or decrease reduces the frequency offset between the carrier frequency and the frequency of the synthesized frequency signal 166, and the frequency of the synthesized frequency signal 166 converges toward the desired frequency offset. This desired frequency offset is determined during receiver design, taking into consideration the channel bandwidth and deviation of subaudio signaling. As an example, a desired frequency offset may be determined to be about 200 Hz for a 12.5 kHz channel bandwidth, although it is to be understood that the desired frequency offset may be larger or smaller, as well.

AFC subsystem 116 includes AFC controller 120, direct current (DC) estimator 122, conversion module 124, lookup table (LUT) entry selector 126, LUT 128, and signal selector 130, in an embodiment. AFC controller 120 may be a centralized or distributed controller, which for the purposes of simplicity, is illustrated as a centralized controller. It is to be understood that various functions of AFC controller 120 may be performed by distinct controller circuitry. Either way, AFC controller 120 provides control signals 182, 184, 186 to signal selector 126, LUT entry selector 126, and DC estimator 122, respectively, as will be described below.

In response to selector control signal 182 provided by AFC controller 120, signal selector 130 provides, as synthesizer control signal 180, either LUT-selected frequency offset signal 178 or DC estimation-based frequency offset signal 176, in an embodiment. As indicated above in conjunction with the discussion of the characteristics of synthesizer control signal 180, LUT-selected frequency offset signal 178 and DC estimation-based frequency offset signal 176 may convey an actual frequency offset value, in an embodiment, or may convey some other value representing a frequency offset. For ease of explanation, the description below assumes that LUT-selected frequency offset signal 178, DC estimation-based frequency offset signal 176, and synthesizer control signal 180 each convey an actual frequency offset value. Those of skill in the art would understand, based on the description herein, how to modify the various components of AFC subsystem 116 and frequency synthesizer 112 in embodiments in which frequency offset signal 178, DC estimation-based frequency offset signal 176, and/or synthesizer control signal 180 convey values other than actual frequency offset values (e.g., signals that convey frequency offsets in some other format).

Via selector control signal 182, AFC controller 120 causes signal selector 130 to provide, as synthesizer control signal 180, LUT-selected frequency offset signal 178 during particular, first time periods. According to an embodiment, the first time periods include: 1) time periods during which an insufficient number of signal samples have been provided to enable DC estimator 122 to perform DC estimation (e.g., at system start up and/or at the beginning of reception of a call or a burst); and 2) time periods that begin when a change in the carrier frequency has occurred (e.g., in conjunction with a handoff to a channel characterized by a different carrier frequency.

At least during the time periods when signal selector 130 provides the LUT-selected frequency offset signal 178 as the synthesizer control signal 180, LUT entry selector 126 selects frequency offset values from LUT 128. More particularly, at the beginning of each one of the first time periods listed above, AFC controller 120 provides a selector control signal 184 to LUT entry selector 126, which causes LUT entry selector 126 to select a frequency offset value from LUT 128.

According to an embodiment, LUT 128 includes a plurality of frequency offset values, which correspond to the channel bandwidth configuration of the receiver and the type of incoming signals 160 (e.g., Continuous Tone Controlled Squelch System (CTCSS), Continuous Digital Controlled Squelch System (CDCSS) (also known as Motorola's Digital Private Line (DPL), and General Electric's Digital Channel Guard (DCG))). In an embodiment, LUT entry selector 126 randomly selects a frequency offset value from LUT 128. In other embodiments, LUT entry selector 126 may select the frequency offset value from LUT 128 pseudo-randomly or in accordance with certain criteria. For example, a desired frequency offset may be determined by, specified to, or known to LUT entry selector 126, and LUT entry selector 126 may select (e.g., randomly or otherwise) from a subset of the entries of LUT 128, which includes the desired frequency offset and a range of frequency offsets on either side of the desired frequency offset (thus defining the “desired frequency offset range”).

According to an embodiment, the desired frequency offset or the desired frequency offset range may be determined based on the sub-audible deviation limit on the channel. For example, the sub-audible deviation limit for a 12.5 kilohertz (kHz) channel bandwidth may be about 400 Hz, and the sub-audible deviation limit for a 25 kHz channel bandwidth may be about 1000 Hz. However the LUT entry selector 126 selects the frequency offset, the selected frequency offset corresponds to an initial frequency offset provided (via LUT-selected frequency offset signal 178 and synthesizer control signal 180) to the frequency synthesizer 112. Frequency synthesizer 112 then uses the initial frequency offset to control the local oscillator 114.

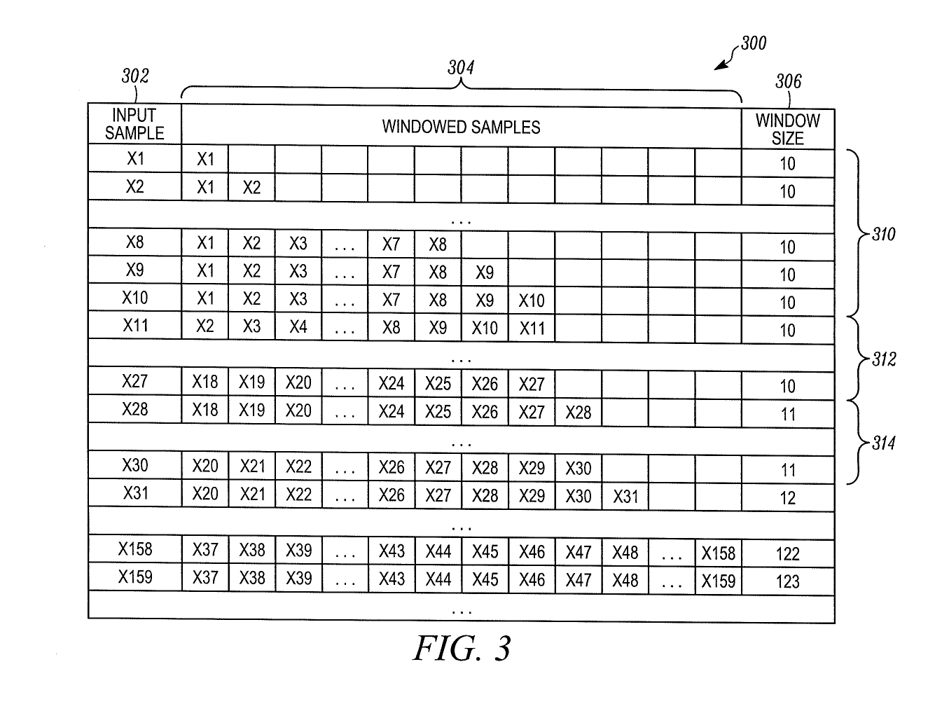

After initializing the frequency synthesizer 112 with a frequency offset value selected from LUT 128, AFC controller 120 determines when to initiate provision of frequency offset estimates based instead on an analysis of DC components present within the baseband samples 172 from discriminator 110. According to an embodiment, AFC controller 120 determines that it is time to initiate provision of DC estimation-based frequency offsets when a sufficient number of baseband samples 172 have been provided to DC estimator 122 for DC estimator 122 to produce an estimate of the DC component present within the baseband samples 172. For example, as will be discussed in more detail later, when discriminator 110 has provided a number of baseband samples 172 that equal or exceed the size of an initial sample selection window (e.g., sample selection window 310, FIG. 3) applied by DC estimator 122, AFC controller 120 may cause the AFC subsystem 116, via signal selector 130, to switch to providing the DC estimation-based frequency offset signal 176 as the synthesizer control signal 180. In alternate embodiments, this determination may be made based on a time trigger (e.g., a time period having elapsed from system startup, the beginning of reception of a call or a burst, and/or a carrier frequency change) or based on the occurrence of some other event.

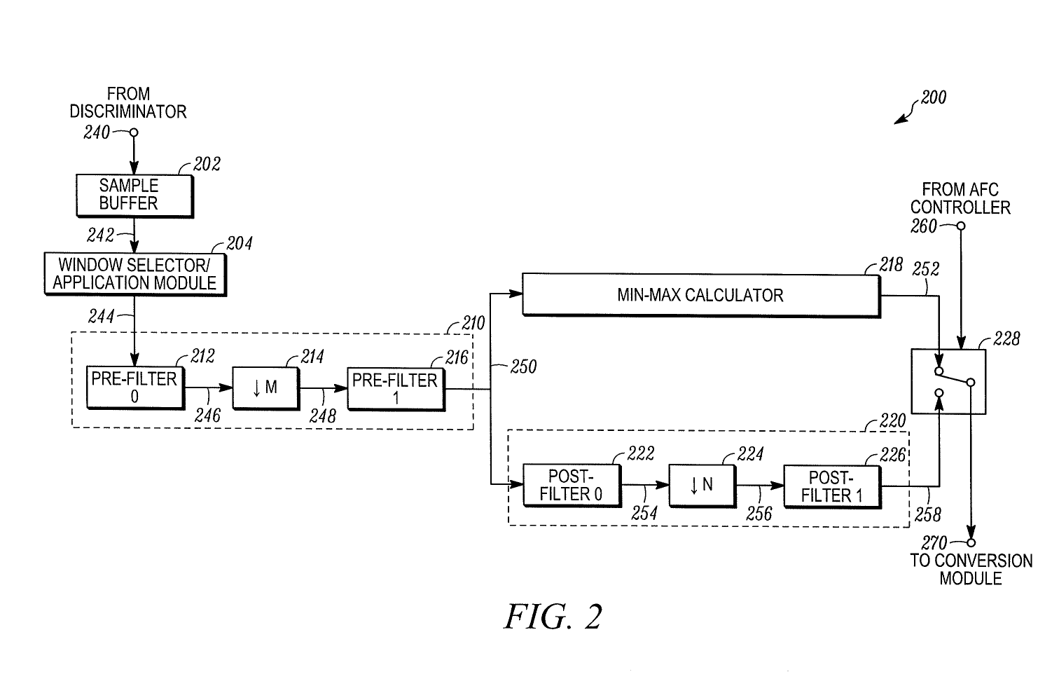

To begin providing the DC estimation-based frequency offset signal 176 as the synthesizer control signal 180, AFC controller 120 provides a selector control signal 182 to signal selector 130 to cause signal selector 130 to provide the DC estimation-based frequency offset signal 176. In addition, AFC controller 120 provides an estimator control signal 186 to DC estimator 122 to cause DC estimator 122 to begin producing estimates 174 of the magnitude of the DC component present in the baseband samples 172 (referred to herein as “DC estimates”). More particularly, via estimator control signal 186, AFC controller 120 initially causes DC estimator 122 to operate in a first operational mode, referred to as a “min-max operations mode.” Later (e.g., after a pre-determined period of time or when the DC estimates 174 or frequency offsets conveyed in frequency offset signal 176 have dropped below pre-determined thresholds), via estimator control signal 186, AFC controller 120 causes DC estimator 122 to operate in a second operational mode, referred to as a “post-filtering operational mode.” In either operational mode, DC estimator 122 produces DC estimates 174 reflecting the DC component present in the baseband samples 172. Embodiments of DC estimator apparatus and methods for producing DC estimates are described in detail in conjunction with FIGS. 2-5, below.

Conversion module 124 is configured to receive the DC estimates 174 from DC estimator 122, and to convert the DC estimates 174 into frequency offset values, which are conveyed in the DC estimation-based frequency offset signal 176. According to an embodiment, conversion module 124 applies a conversion factor to the DC estimates 174 in order to produce the frequency offset values. In other embodiments, conversion module 124 may apply other mathematical conversions, or may use the DC estimates 174 as references into a table (not shown) that correlates DC estimates 174 with frequency offset values. Either way, conversion module 124 conveys the frequency offsets (via DC estimation-based frequency offset signal 176 and signal selector 130) to frequency synthesizer 112, which synthesizes a synthesized frequency signal 166 for provision to down-converting mixer 106, as discussed above.

FIG. 2 is a simplified block diagram of a DC estimator 200 of an AFC subsystem (e.g., DC estimator 122 of AFC subsystem 116, FIG. 1), in accordance with some embodiments. As discussed above, DC estimator 200 is configured to produce estimates of the DC component present in a received signal, after down-conversion (e.g., signal 168, FIG. 1). As will be discussed in detail below, DC estimator 200 performs sequential DC component estimation processes, thus producing a sequence of DC estimates 270 that may be converted (e.g., by conversion module 124, FIG. 1) into frequency offsets that may be used to program the local oscillator (e.g., local oscillator 114, FIG. 1). Not all of the DC estimates 270 need to be used to program the local oscillator. Instead, other portions of the system may determine when the local oscillator should be programmed (e.g., at pre-determined times or based on some other triggering event). When the local oscillator is to be programmed, the frequency offset corresponding to the most recently produced DC estimate 270 is used to program the local oscillator.

DC estimator 200 includes a sample buffer 202, a window selector/application module 204 (referred to simply as a “window module,” below), a pre-filter 210, a min-max calculator 218, a post-filter 220, and an output selector 228, in an embodiment. DC estimator 200 receives incoming baseband samples (e.g., baseband samples 172, FIG. 1) from a discriminator (e.g., discriminator 110, FIG. 1), and stores the baseband samples in sample buffer 202 in a sequential order. As discussed previously, the baseband samples may be characterized by a sampling rate of about 20 ks/s to 30 ks/s, or some other sampling rate. For purpose of explanation only, an example sampling rate of 20 ks/s will be used below.

As the samples fill the sample buffer 202, window module 204 is configured iteratively to apply analysis windows to the samples by selecting, for further analysis, sets of sequential samples. For each iteration, the number of samples in each set is referred to as the “window size.” As will be explained in more detail below, the window size is varied from a relatively small, initial window size to a relatively large, maximum window size between a time when the sample buffer 202 first begins receiving samples until the DC estimator 200 reaches a steady state. In addition, the analysis windows slide through the samples in the sample buffer 202, so that each analysis window is applied to more recently stored (buffered) samples. FIGS. 3 through 5 are provided to better explain this concept.

FIG. 3 is a table 300 illustrating how time-varying sample selection windows are applied to incoming baseband samples, in accordance with some embodiments. In FIG. 3, each row corresponds to the contents of sample buffer 202 at a time when a new baseband sample is stored in the sample buffer 202, and the rows are arranged in a sequential order. Column 302 indicates the sample that has been most recently stored in the sample buffer 202. Columns 304 indicate the samples that have been selected for analysis during a particular iteration of the DC estimation process (i.e., the samples in sample buffer 202 to which the analysis window has been applied), and column 306 indicates the current size of the analysis window. Specific samples are referred to using the convention “Xn,” where n indicates the number of the sample in the received sequence of samples.

For purposes of example, an initial window size of 10 is used, although it is to be understood that the initial window size may be smaller or larger, as well. Rows 310 represent the first 10 samples that are stored in the sample buffer 202. Although it is not required that an analysis iteration (i.e., the estimation of a DC component) be performed each time a new sample is stored in the sample buffer 202, analysis iterations may be performed that frequently. In addition, it is not required that each analysis window capture the most recently stored sample (e.g., there may be some delay in the application of the analysis window as the sample buffer 202 fills), the analysis window may be applied to capture the most recently stored sample, as illustrated in FIG. 3.

In the example shown in FIG. 3, as the sample buffer 302 initially begins to fill (as represented in rows 310), and as long as the number of samples in the sample buffer 202 is less than or equal to the initial window size, the analysis window is applied to select all of the samples in the sample buffer 202 for analysis, and the size of the analysis window remains fixed at the initial window size (i.e., 10, in the example). Accordingly, during the time period when samples X1 through X10 are stored in the sample buffer 202, the first sample (X1) is included in the analysis window.

Once the number of samples in the sample buffer 202 exceeds the initial window size, the analysis window begins to slide through the sample buffer 202, in order to capture more recently stored samples. Until a window size increase trigger occurs, however, the size of the analysis window remains fixed at the initial window size, as represented in rows 312. For example, for the first row of rows 312 (corresponding to storage of input sample X11 in the sample buffer 202), the analysis window has moved to capture samples X2 through X11 (i.e., sample X1 is no longer captured by the analysis window). This holds true through the storage of sample X27, in the illustrated example, at which time the analysis window has sequentially slid through the sample buffer 202 to capture samples X18 through X27.

As indicated above, when a window size increase trigger occurs, the size of the analysis window is increased. Window size increase triggers may include, for example, a pre-defined time period having elapsed, a pre-defined total number of samples being stored in the sample buffer 202, a pre-defined number of new samples being stored in the sample buffer 202, and a pre-defined number of window application and/or analysis iterations having been performed.

Just prior to the next application of the analysis window, a window size increase trigger occurs, and the size of the analysis window is increased. In the example, the analysis window size is increased by one sample to a window size of 11 (although the analysis window size, alternatively, could be increased by an increment that is greater than one sample). Accordingly, in the first row of rows 314, the analysis window captures samples X18 through X28 (11 samples). For subsequently stored samples, and until another window size increase trigger occurs, the window size remains at 11, and the analysis window slides through the sample buffer 202 to capture more recently stored samples. When the next window size increase trigger occurs (e.g., just prior to storing sample X31), the window size is again increased (i.e., to 12 samples), and application of the analysis window to the buffered samples proceeds as discussed above. In an embodiment, the analysis window size is increased up to a maximum window size (e.g., 140 samples, or some other number), at which time the window size remains fixed, but continues to slide to capture more recently stored samples, for a remainder of the time that the baseband samples are processed in conjunction with the current transmission. The maximum window size may be selected based on the sampling rate or some other factor. For example, a larger maximum window size may be selected for a relatively high sampling rate, and a smaller maximum window size may be selected for a relatively low sampling rate, or vice versa.

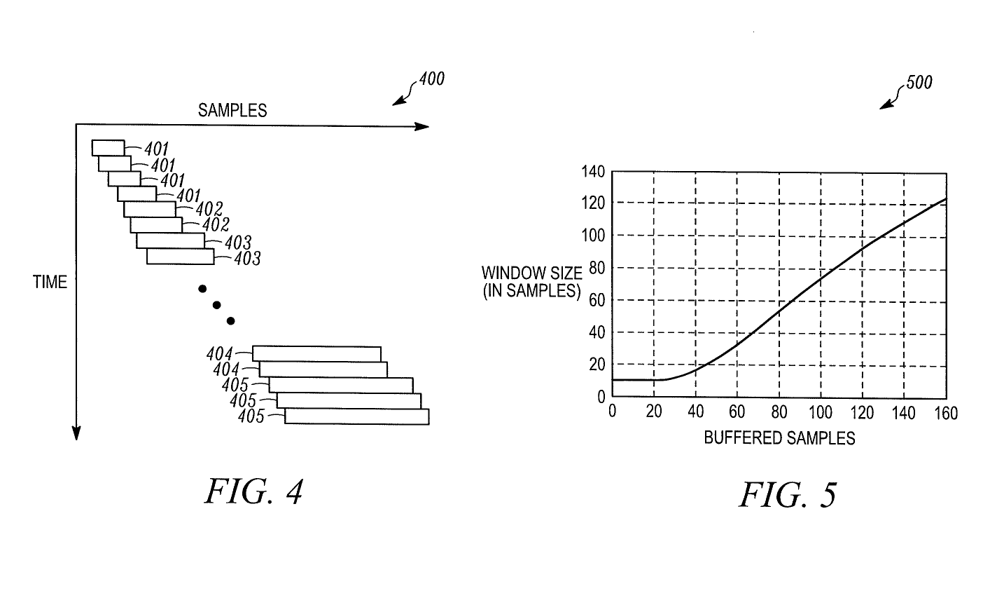

The concept of the varying and sliding analysis window is further illustrated in FIG. 4, which is a chart 400 illustrating time-varying sample selection windows 401-405, in accordance with various example embodiments. In FIG. 4, the “SAMPLES” axis indicates the sample numbers of samples stored in the sample buffer 202, in sequential order from left to right, and the “TIME” axis indicates discrete times at which the analysis window is applied to select samples in the sample buffer 202, in chronological order from top to bottom. Beginning at the application of a first sample window 401 of an initial analysis size (e.g., 10 or some other size), and as time progresses (i.e., as more samples are stored in the sample buffer 202), the size of analysis window 401 temporarily remains fixed as it is iteratively applied to more recently stored samples in the sample buffer 202. When a window size trigger occurs, an incrementally larger analysis window 402 is applied to more recently stored samples. This process is repeated, as shown in FIG. 4, with consecutively larger analysis windows 403, 404, 405 being applied to more recently stored samples. Eventually, the analysis window (e.g., analysis window 405) reaches a maximum window size (e.g., 140 samples, or some other number).

FIG. 5 is a graph 500 plotting window size with respect to a number of buffered samples, in accordance with various example embodiments. As FIG. 5 illustrates, and as discussed previously, as the number of buffered samples increases, the window size also increases from an initial window size (e.g., 10 samples in FIG. 5) to a maximum window size (e.g., 140 samples, or some other number). In an embodiment, window size increases with respect to the number of buffered samples may be exponential, incremental, or in accordance with some other mathematical function. Each time DC estimator 200 is to perform an iteration of estimating a DC component of the baseband samples in sample buffer 202, the window size may be calculated based on the window size determination function. Alternatively, the window size may be calculated each time a window size trigger occurs.

Referring again to FIG. 2, after window module 204 selects a number of baseband samples 244 from the sample buffer 202, DC estimator 200 produces an estimate 270 of a DC component present in the selected baseband samples using pre-filter 210, and either min-max calculator 218 or post-filter 220. The DC estimate 270 is produced using min-max calculator 218 for a first period of time after DC estimator 200 has been invoked by the AFC controller (e.g., AFC controller 120, FIG. 1) to provide the DC estimates 270 (e.g., after LUT entry selector 126, FIG. 1 provided an initial frequency offset selected from LUT 128, FIG. 1). The DC estimate 270 is produced using post-filter 220 after expiration of the first period of time (e.g., after a pre-determined period of time or when a DC estimate 270 (e.g., DC estimate 174, FIG. 1) or a frequency offset derived therefrom (e.g., a frequency offset determined by conversion module 124, FIG. 1, and conveyed in frequency offset signal 176, FIG. 1) has dropped below a pre-determined threshold.

DC estimator 200 produces the DC component using pre-filter 210 and min-max calculator 218 when an estimator control signal 260 (e.g., estimator control signal 186, FIG. 1) from the AFC controller (e.g., AFC controller 120, FIG. 1) indicates that DC estimator 200 should operate in the min-max operational mode. In such a case, the estimator control signal 260 causes output selector 228 to output a DC estimate 252 produced by min-max calculator 218 as a DC estimate 270 (e.g., DC estimate 174, FIG. 1) that is provided to the conversion module (e.g., conversion module 124, FIG. 1). Conversely, DC estimator 200 produces the DC component using pre-filter 210 and post-filter 220 when the estimator control signal 260 from the AFC controller indicates that DC estimator 200 should operate in the post-filtering operational mode. In such a case, the estimator control signal 260 causes output selector 228 to output a DC estimate 258 produced by post-filter 220 as the DC estimate 270 that is provided to the conversion module. In either operational mode, DC estimator 200 iteratively produces DC estimates 270 reflecting the DC component present in the baseband samples stored in sample buffer 202 and selected by window module 204.

In both the min-max and post-filtering operational modes, the baseband samples 244 selected by window module 204 are processed by pre-filter 210. According to an embodiment, pre-filter 210 is a cascaded, down-sampling low pass filter (LPF), which includes a first pre-filter stage 212 (“pre-filter 0”), a down-sampler 214, and a second pre-filter stage 216 (“pre-filter 1”). The first and second pre-filter stages 212, 216 are used to filter out relatively high-frequency components present in the baseband samples 244, in order to progressively isolate the DC component present in the baseband samples 244.

First pre-filter stage 212 is an LPF stage having a first cutoff frequency. For example, the first cutoff frequency may be about 50 Hz, although the first cutoff frequency may be lower or higher, as well. By processing the selected baseband samples 244, the first pre-filtering stage 212 produces first pre-filtered samples 246.

According to an embodiment, down-sampling (i.e., by down-sampler 214) is implemented between the first and second pre-filter stages 212, 216 to facilitate a very narrow pass-band of pre-filter 210. Down-sampler 214 down-samples the first pre-filtered samples 246 by a first down-sampling factor of M, to produce a down-sampled set of pre-filtered samples 248. For example, the first down-sampling factor may be about 10, although the first down-sampling factor may be smaller or larger, as well.

Second pre-filter stage 216 also is an LPF stage, and second pre-filter stage 216 has a second cutoff frequency that is less than the first cutoff frequency of first pre-filter stage 212. For example, the second cutoff frequency may be about 40 Hz, although the second cutoff frequency may be lower or higher, as well. By processing the down-sampled set of pre-filtered samples 248, the second pre-filtering stage 216 produces second pre-filtered samples 250 (referred to simply as “pre-filtered samples” 250, below). Pre-filter 210 improves the signal-to-noise ratio (SNR) of the input signal represented by the selected baseband samples 244, which may compensate for sensitivity of min-max calculator 218 to noise that may be present in the input signal.

When output selector 228 is implemented on the output side of min-max calculator 218 and post-filter 220, the pre-filtered samples 250 are provided to and processed by both min-max calculator 218 and post-filter 220, although output selector 228 will only produce the outputs 252 or 258 from either min-max calculator 218 or post-filter 220 in accordance with the estimator control signal 260, as discussed previously. Alternatively, a selector (not illustrated) may be implemented on the input side of min-max calculator 218 and post-filter 220, and the pre-filtered samples 250 would be provided to and processed by only one of min-max calculator 218 and post-filter 220.

Either way, when DC estimator 200 is configured to operate in the min-max operational mode, min-max calculator 218 produces DC estimates 252 that are output from DC estimator 200 as the output DC estimates 270 (e.g., DC estimates 174, FIG. 1). According to an embodiment, min-max calculator 218 produces the DC estimates 252 using the following min-max formula:

$$DC estimate = \frac{min ( X ( n ) ) + max ( X ( n ) )}{2} ,$$

where min(X(n)) is the value of the pre-filtered sample 250 having the smallest amplitude of all of the pre-filtered samples 250 being analyzed during the current iteration, and max (X(n)) is the value of the pre-filtered sample 250 having the largest amplitude of all of the pre-filtered samples 250 being analyzed during the current iteration. Accordingly, the min-max calculator 218 produces DC estimate 252 as an intermediate value between a first amplitude of a first sample (i.e., the pre-filtered sample 250 having the smallest amplitude) and a second amplitude of a second sample (i.e., the pre-filtered sample 250 having the largest amplitude).

Conversely, when DC estimator 200 is configured to operate in the post-filtering operational mode, post-filter 220 produces DC estimates 258 that are output from DC estimator 200 as the output DC estimates 270 (e.g., DC estimates 174, FIG. 1).

According to an embodiment, post-filter 220 is a cascaded, down-sampling LPF, which includes a first post-filter stage 222 (“post-filter 0”), a down-sampler 224, and a second post-filter stage 226 (“post-filter 1”). The first and second post-filter stages 222, 226 are used to even further filter out relatively high-frequency components present in the pre-filtered samples 250, in order to further progressively isolate the DC component present in the pre-filtered samples 250.

First post-filter stage 222 is an LPF stage having a third cutoff frequency that is less than the second cutoff frequency of second pre-filter stage 216. For example, the third cutoff frequency may be about 3 Hz, although the third cutoff frequency may be lower or higher, as well. By processing the pre-filtered samples 250, the first post-filter stage 222 produces first post-filtered samples 254.

According to an embodiment, further down-sampling (i.e., by down-sampler 224) is implemented between the first and second post-filter stages 222, 226 to facilitate an even narrower pass-band of post-filter 220 than was implemented by pre-filter 210. Down-sampler 224 down-samples the first post-filtered samples 254 by a second down-sampling factor of N, to produce a down-sampled set of post-filtered samples 256. For example, the second down-sampling factor may be about 10, although the second down-sampling factor may be smaller or larger, as well. In an embodiment, the second down-sampling factor, N, is the same as the first down sampling factor, M, implemented by the down-sampler 214 in pre-filter 210, although the first and second down-sampling factors, M and N, may be different from each other, as well.

Second post-filter stage 226 also is an LPF stage, and second post-filter stage 226 has a fourth cutoff frequency that is less than the third cutoff frequency of first post-filter stage 222. For example, the fourth cutoff frequency may be about 2 Hz, although the fourth cutoff frequency may be lower or higher, as well. By processing the down-sampled set of post-filtered samples 256, the second post-filter stage 226 produces second post-filtered samples corresponding to DC estimate 258.

Once again, while DC estimator 200 is in the min-max operational mode (as governed by estimator control signal 260 from the AFC controller), output selector 228 produces DC estimates 252 produced by min-max calculator 218 as DC estimates 270 (e.g., DC estimates 174, FIG. 1) output to the conversion module (e.g., conversion module 124, FIG. 1). Conversely, while DC estimator 200 is in the post-filtering operational mode (as governed by estimator control signal 260 from the AFC controller), output selector 228 produces DC estimates 258 produced by post filter 220 as DC estimates 270 output to the conversion module.

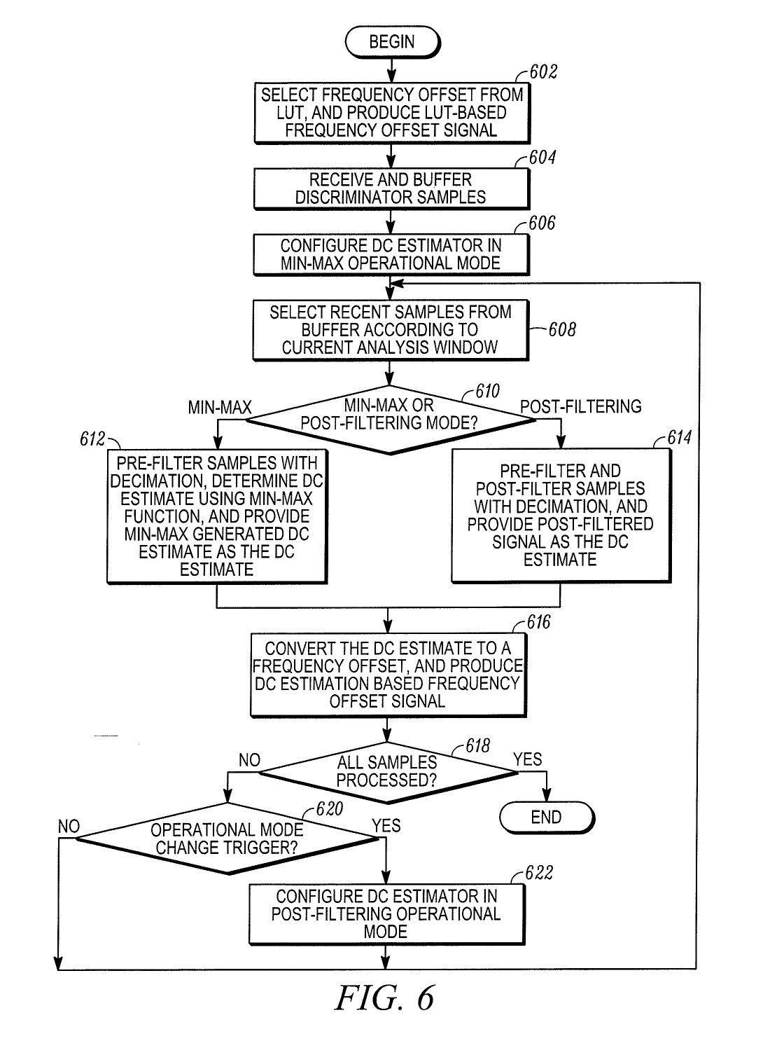

FIG. 6 is a flowchart of a method of producing a frequency offset associated with performing automatic frequency control, in accordance with some embodiments. As each of the various method steps depicted in FIG. 6 have been previously described in conjunction with the description of the various apparatus embodiments, these steps will be discussed only briefly, below.

The method may begin, in block 602, by selecting a frequency offset value from an LUT (e.g., LUT 128, FIG. 1), and producing an LUT-based frequency offset signal (e.g., signal 178, FIG. 1) that may be used to program the local oscillator (e.g., local oscillator 114, FIG. 1) of the frequency synthesizer (e.g., frequency synthesizer 112, FIG. 1).

In block 604, the DC estimator (e.g., DC estimator 122. 200, FIGS. 1, 2) receives and buffers baseband samples (e.g., baseband samples 172, 240, FIGS. 1, 2) from the discriminator (e.g., discriminator 110, FIG. 1). The reception and buffering of baseband samples may begin in parallel with or prior to performing block 602, and is performed continuously throughout execution of the remainder of the method (or at least until all data associated with the current transmission has been received).

In block 606, via a control signal (e.g., estimator control signal 186, FIG. 1) from the AFC controller (e.g., AFC controller 120, FIG. 1), DC estimate generation by the DC estimator is initiated, and the DC estimator is configured in the min-max operational mode. This initiates the generation of a min-max based DC estimate. In block 608, a set of baseband samples to be analyzed are selected from the sample buffer (e.g., sample buffer 202, FIG. 2). As discussed previously, the samples are selected based on an analysis window, which has a time-varying width, and which is slid through the sample buffer to capture recently buffered samples as the DC estimate generation iterations are performed.

When the DC estimator is in the min-max operational mode, as indicated by decision block 610, the DC estimator performs pre-filtering (e.g., using pre-filter 210, FIG. 2), and determines a DC estimate using a min-max function (e.g., by min-max calculator 218, FIG. 2). The min-max generated DC estimate (e.g., DC estimate 252, FIG. 2) is provided as the output DC estimate (e.g., DC estimate 174, 270, FIGS. 1, 2) of the DC estimator.

In block 616, the DC estimate provided by the DC estimator is converted (e.g., by conversion module 124, FIG. 1) into a frequency offset, and the frequency offset is conveyed to the frequency synthesizer (e.g., frequency synthesizer 112, FIG. 1) to enable the frequency synthesizer to adjust the frequency produced the local oscillator (e.g., local oscillator 114, FIG. 1).

When all baseband samples in the sample buffer have been processed, as indicated by decision block 618, the method ends. Otherwise, if no trigger has occurred that would cause the system to change its operational mode from the min-max operational mode to the post-filtering operational mode, as indicated by decision block 620, then blocks 608, 610, 612, and 616 are iteratively performed. If a trigger has occurred that would cause the system to change its operational mode (e.g., after a pre-determined period of time has elapsed or when the DC estimates 174, 270 (FIGS. 1, 2) or frequency offsets conveyed in frequency offset signal 176 (FIG. 1) have dropped below pre-determined thresholds), then the DC estimator is configured, via a control signal (e.g., estimator control signal 186, FIG. 1) from the AFC controller (e.g., AFC controller 120, FIG. 1), in the post-filtering operational mode. This initiates the generation of DC estimate using a pre-filter (e.g., pre-filter 210, FIG. 2) and a post-filter (e.g., post-filter 220, FIG. 2). Accordingly, in block 608, a set of baseband samples to be analyzed are selected from the sample buffer, as discussed above.

Since the DC estimator is in the post-filtering operational mode, as indicated by decision block 610, the DC estimator performs pre-filtering (e.g., using pre-filter 210, FIG. 2), and post-filtering (e.g., using post-filter 220, FIG. 2), in order to determine a DC estimate (e.g., DC estimate 258, FIG. 2), which is provided as the output DC estimate (e.g., DC estimate 174, 270, FIGS. 1, 2) of the DC estimator.

Once again, in block 616, the DC estimate provided by the DC estimator is converted (e.g., by conversion module 124, FIG. 1) into a frequency offset, and the frequency offset is conveyed to the frequency synthesizer (e.g., frequency synthesizer 112, FIG. 1) to enable the frequency synthesizer to adjust the frequency produced the local oscillator (e.g., local oscillator 114, FIG. 1). DC estimates in the post-filtering operational mode are iteratively determined until all samples are processed, as indicated by decision block 618, at which time the method ends.

Embodiments discussed above may have certain advantages over other apparatus and methods for performing automatic frequency control. For example, the sliding and variable length windows implemented by window module 204 (FIG. 2) decreases convergence times and estimation errors, when compared with other apparatus and methods. In addition, the down-sampler (e.g., down-sampler 214, FIG. 2) implemented in the pre-filter (e.g., pre-filter 210, FIG. 2) of the DC estimator (e.g., DC estimator 200, FIG. 2) improves the SNR of the input signals to the min-max calculator (e.g., min-max calculator 218, FIG. 2). The cascaded, narrow-band, low pass filters (e.g., filter stages 212, 216, 222, 226, FIG. 2) with dual down-sampling (e.g., by down-samplers 214, 224, FIG. 2) may provide more accurate tracking of DC components. Also, switching from the min-max operational mode to the post-filtering operational mode after an initial period of automatic frequency control may further reduce estimation variation in subsequent tracking of frequency offsets.

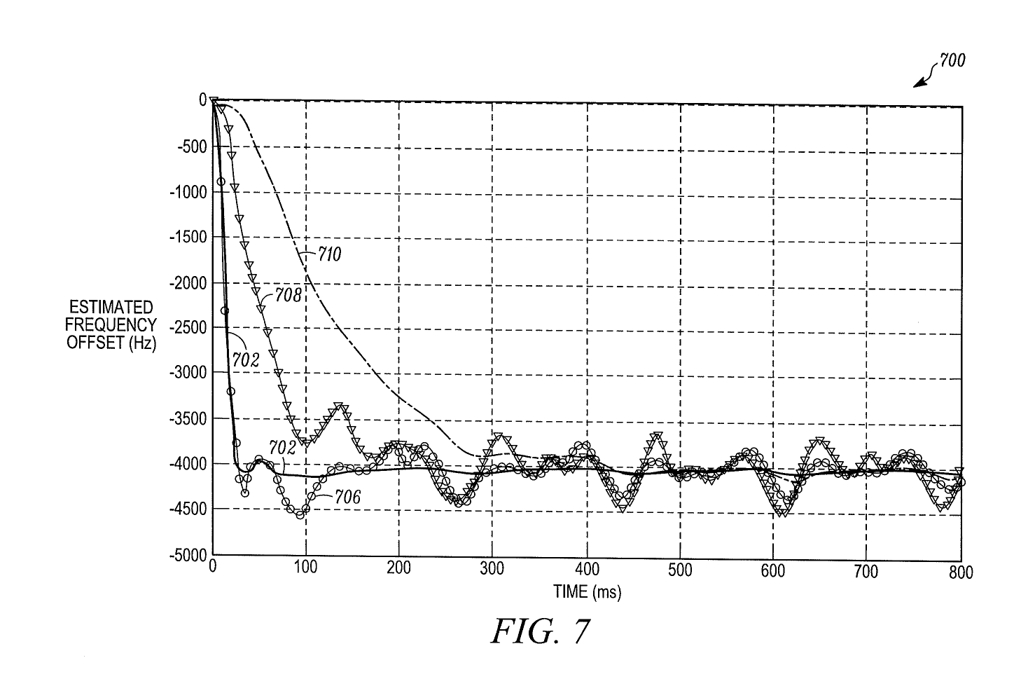

FIG. 7 is a graph 700 plotting estimated frequency offsets with respect to time, and comparing the performance of AFC apparatus and methods, in accordance with various embodiments, with techniques for performing AFC that do not include the combination of apparatus and methods employed using the various embodiments. In generating the results depicted in FIG. 7 a desired frequency offset of 4000 Hz was implemented.

Trace 702 corresponds to estimated frequency offsets (in Hz) from the desired frequency offset, with respect to time, from initiation of a frequency offset estimation process (i.e., corresponding to time=0 milliseconds (ms)) for a system (e.g., DC estimator 200, FIG. 2) and AFC method (e.g., the method of FIG. 6), in accordance with embodiments discussed above. Trace 706 corresponds to estimated frequency offsets with respect to time for an alternate system that implements a sliding and variable sized analysis window that calculates an average of the windowed samples, rather than performing a min-max calculation. Trace 708 corresponds to estimated frequency offsets with respect to time for an alternate system that implements low pass filter-based AFC. Finally, trace 710 corresponds to estimated frequency offsets with respect to time for an alternate system that implements cascaded, down-sampling filtering, but does not implement a sliding and variable sized analysis window or a min-max calculation.

The depicted results indicate that, by implementing the combination of features discussed above with respect to the various embodiments, significant performance enhancements can be achieved. For example, systems that implemented in accordance with the various embodiments (e.g., conveyed by trace 702) are characterized by a significantly shorter convergence time (e.g., on the order of about 20 ms) when compared with the convergence times of systems that do not implement a sliding and varying sized analysis window (e.g., conveyed by traces 708, 710). In addition, systems that implemented in accordance with the various embodiments (e.g., conveyed by trace 702) are characterized by significantly smaller frequency offset estimation errors (as indicated by the relative flatness of trace 702) when compared with the estimation errors of systems that do not implement cascaded filtering and/or min-max calculations (e.g., conveyed by traces 706, 708, 710).

In the foregoing specification, specific embodiments have been described. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of present teachings.

The benefits, advantages, solutions to problems, and any element(s) that may cause any benefit, advantage, or solution to occur or become more pronounced are not to be construed as a critical, required, or essential features or elements of any or all the claims. The invention is defined solely by the appended claims including any amendments made during the pendency of this application and all equivalents of those claims as issued.

Moreover in this document, relational terms such as first and second, top and bottom, and the like may be used solely to distinguish one entity or action from another entity or action without necessarily requiring or implying any actual such relationship or order between such entities or actions. The terms “comprises,” “comprising,” “has”, “having,” “includes”, “including,” “contains”, “containing” or any other variation thereof, are intended to cover a non-exclusive inclusion, such that a process, method, article, or apparatus that comprises, has, includes, contains a list of elements does not include only those elements but may include other elements not expressly listed or inherent to such process, method, article, or apparatus. An element proceeded by “comprises . . . a”, “has . . . a”, “includes . . . a”, “contains . . . a” does not, without more constraints, preclude the existence of additional identical elements in the process, method, article, or apparatus that comprises, has, includes, contains the element. The terms “a” and “an” are defined as one or more unless explicitly stated otherwise herein. The terms “substantially”, “essentially”, “approximately”, “about” or any other version thereof, are defined as being close to as understood by one of ordinary skill in the art, and in one non-limiting embodiment the term is defined to be within 10%, in another embodiment within 5%, in another embodiment within 1% and in another embodiment within 0.5%. The term “coupled” as used herein is defined as connected, although not necessarily directly and not necessarily mechanically. A device or structure that is “configured” in a certain way is configured in at least that way, but may also be configured in ways that are not listed.

It will be appreciated that some embodiments may be comprised of one or more generic or specialized processors (or “processing devices”) such as microprocessors, digital signal processors, customized processors and field programmable gate arrays (FPGAs) and unique stored program instructions (including both software and firmware) that control the one or more processors to implement, in conjunction with certain non-processor circuits, some, most, or all of the functions of the method and/or apparatus described herein. Alternatively, some or all functions could be implemented by a state machine that has no stored program instructions, or in one or more application specific integrated circuits (ASICs), in which each function or some combinations of certain of the functions are implemented as custom logic. Of course, a combination of the two approaches could be used.

Moreover, an embodiment can be implemented as a computer-readable storage medium having computer readable code stored thereon for programming a computer (e.g., comprising a processor) to perform a method as described and claimed herein. Examples of such computer-readable storage mediums include, but are not limited to, a hard disk, a CD-ROM, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory) and a Flash memory. Further, it is expected that one of ordinary skill, notwithstanding possibly significant effort and many design choices motivated by, for example, available time, current technology, and economic considerations, when guided by the concepts and principles disclosed herein will be readily capable of generating such software instructions and programs and ICs with minimal experimentation.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

We claim:

1. A method for performing automatic frequency control based on a received signal, the method comprising:
storing digital samples generated based on the received signal in a buffer in a sequential order, resulting in a plurality of buffered samples; and
performing multiple iterations of a first direct current (DC) component estimation processes by iteratively:
applying an analysis window to more recently stored ones of the buffered samples in order to identify a set of the buffered samples, wherein the analysis window has a variable window size,
within the set of buffered samples, determining an intermediate value between a first amplitude of a first sample and a second amplitude of a second sample, and
between at least some of the multiple iterations, increasing a number of samples that defines the variable window size of the analysis window.

2. The method of claim 1, wherein the first sample has a largest amplitude within the set, and the second sample has a smallest amplitude within the set, and wherein determining the intermediate value comprises:
performing a min-max calculation using the first amplitude and the second amplitude, wherein the min-max calculation is performed by adding the first amplitude and the second amplitude, and dividing a resulting sum by two.

3. The method of claim 1, wherein increasing the number of samples that defines the variable window size is performed in response to an occurrence of a window size increase trigger, wherein the window size increase trigger includes at least one event selected from a group consisting of a pre-defined time period having elapsed, a pre-defined total number of samples being stored in the buffer, a pre-defined number of new samples being stored in the buffer, and a pre-defined number of the multiple iterations having been performed.

4. The method of claim 1, further comprising:
receiving a radio frequency (RF) signal from a remote device;
down-converting the RF signal using a local oscillator signal produced by a local oscillator;
demodulating the down-converted RF signal to produce a plurality of baseband samples; and
processing the plurality of baseband samples to produce the digital samples.

5. The method of claim 4, wherein processing the plurality of baseband samples comprises:
applying a first low pass filter stage to the plurality of baseband samples, resulting in first filtered samples;
decimating the first filtered samples by a factor of N to produce decimated filtered samples; and
applying a second low pass filter stage to the decimated filtered samples, resulting in the digital samples.

6. The method of claim 4, further comprising:
producing the intermediate value as an estimate of the DC component;
producing a control signal based on the estimate of the DC component; and
adjusting the local oscillator signal based on the control signal.

7. The method of claim 1, further comprising:
when a processing mode change trigger occurs, discontinuing performing the first DC component estimation processes; and
performing a second DC component estimation process by
applying a first post-filter stage to the buffered samples, resulting in first filtered samples,
decimating the first filtered samples by a factor of M to produce decimated filtered samples, and
applying a second post-filter stage to the decimated filtered samples, resulting in an estimate of the DC component.

8. The method of claim 7, wherein the processing mode change trigger comprises at least one event selected from a group consisting of a pre-defined time period having elapsed, a pre-defined number of intermediate values having been produced, and a pre-defined level of convergence of the DC component having been detected.

9. A method for controlling a local oscillator of a radio frequency (RF) receiver in conjunction with performing automatic frequency control, the method comprising:
down-converting an RF signal received from a remote device using a local oscillator signal produced by the local oscillator;
demodulating and processing the down-converted RF signal to produce a plurality of buffered samples;
as the plurality of buffered samples are produced, performing multiple iterations of:
selecting a set of more recently produced ones of the buffered samples, wherein the set includes buffered samples that are encompassed by an analysis window with a window size that increases between at least some of the multiple iterations, and
determining an intermediate value between a first amplitude of a first sample of the set and a second amplitude of a second sample of the set;
wherein the multiple iterations result in a plurality of intermediate values determined using differently sized analysis windows, and the method further comprises:
producing at least one of the intermediate values as an estimate of a DC component of the RF signal; and
adjusting a frequency of the local oscillator signal based on the estimate of the DC component.

10. The method of claim 9, wherein the first sample has a largest amplitude within the set, and the second sample has a smallest amplitude within the set, and wherein determining the intermediate value comprises:
performing a min-max calculation using the first amplitude and the second amplitude, wherein the min-max calculation is performed by adding the first amplitude and the second amplitude, and dividing a resulting sum by two.

11. The method of claim 9, wherein demodulating and processing the down-converted RF signal comprises:
demodulating the down-converted RF signal to produce a plurality of baseband samples at a first sample rate;
applying a first low pass filter stage to the plurality of baseband samples, resulting in first filtered samples;
decimating the first filtered samples by a factor of N to produce decimated filtered samples at a second sample rate that is less than the first sample rate; and
applying a second low pass filter stage to the decimated filtered samples, resulting in the plurality of buffered samples.

12. The method of claim 9, further comprising:
when a processing mode change trigger occurs, discontinuing producing at least one of the intermediate values as the estimate of the DC component of the RF signal, and alternatively:
applying a first post-filter stage to the buffered samples, resulting in first filtered samples;
decimating the first filtered samples by a factor of M to produce decimated filtered samples; and
applying a second post-filter stage to the decimated filtered samples to produce the estimate of the DC component.

13. The method of claim 9, wherein adjusting the frequency of the local oscillator signal comprises:
converting the estimate of the DC component to a local oscillator control signal; and
providing the local oscillator control signal to the local oscillator.

14. An automatic frequency control system of a receiver, the system comprising:
a buffer configured to store buffered samples in a sequential order, wherein the buffered samples represent a received signal; and
a direct current (DC) estimator configured to perform multiple iterations of a first DC component estimation processes using the buffered samples by iteratively:
identifying a set of the buffered samples that falls within an analysis window when the analysis window is applied to more recently stored ones of the buffered samples, wherein the analysis window has a variable window size,
within the set of buffered samples, determining an intermediate value between a first amplitude of a first sample and a second amplitude of a second sample, and
when a window size increase trigger occurs, increasing a number of samples that defines the variable window size of the analysis window.

15. The system of claim 14, wherein the first sample has a largest amplitude within the set, and the second sample has a smallest amplitude within the set, and wherein the DC estimator comprises:
a min-max calculator configured to determine the intermediate value by adding the first amplitude and the second amplitude, and dividing a resulting sum by two.

16. The system of claim 14, further comprising:
a local oscillator configured to receive a control signal that is determined based on the intermediate value, and to produce a local oscillator signal in response to the control signal;
a down-converting mixer configured to down-convert a radio frequency (RF) signal received from a remote device using the local oscillator signal; and
a demodulator configured to demodulate the down-converted RF signal, resulting in a plurality of digital samples that are processed to produce the buffered samples.

17. The system of claim 16, further comprising:
a conversion module configured to receive the intermediate value, and to generate the control signal based on the intermediate value.

18. The system of claim 14, further comprising:
a first pre-filter stage configured receive a plurality of digital samples representing the received signal at a first sample rate, and to low pass filter the plurality of digital samples;
a decimator configured to down-sample the first filtered samples to a second sample rate, resulting in a set of decimated samples; and
a second pre-filter stage configured to low pass filter the set of decimated samples in order to produce the buffered samples.

19. The system of claim 14, wherein the DC estimator is further configured to perform a second DC component estimation process and the DC estimator further comprises:
a first post-filter stage configured to low pass filter the buffered samples, resulting in first filtered samples,
a decimator configured to down-sample the first filtered samples to a second sample rate, resulting in a set of decimated samples, and
a second post-filter stage configured to low pass filter the decimated samples to produce an estimate of a DC component of the received signal.

20. The system of claim 19, further comprising:
a processing mode selector configured to control whether the buffered samples are processed using the min-max calculator or the first post-filter stage, the decimator, and the second post-filter stage.

21. A direct conversion receiver system comprising:
a lookup table that includes a plurality of frequency offset values, wherein each of the plurality of frequency offset values corresponds to a possible frequency offset between a local oscillator of the receiver system and a carrier frequency onto which information within an incoming signal is modulated, wherein the possible frequency offset is within a desired frequency offset range within which the receiver system should operate;
a lookup table entry selector configured to select an initial frequency offset value from the lookup table at a first time, wherein the initial frequency offset value is applied to the local oscillator;
a DC estimator that is dynamically configurable to produce DC estimates of a DC component in a down-converted and digitized representation of the incoming signal, which is represented as a plurality of baseband samples; and
a controller configured to determine when to adjust the local oscillator using the DC estimates by the DC estimator.

22. The receiver system of claim 21, wherein the lookup table entry selector selects the frequency offset value from the lookup table randomly.

23. The receiver system of claim 21, wherein the frequency offset values in the lookup table are dependent on a receiver channel bandwidth configuration.

24. The receiver system of claim 21, wherein the desired frequency offset range is determined based on sub-audible deviation limits on a channel over which the incoming signal is received.

25. The receiver system of claim 21, wherein the desired frequency offset range includes a desired frequency offset and a range of frequency offsets around the desired frequency offset.

26. The receiver system of claim 21, wherein the initial frequency offset value is applied to the local oscillator when a change in a frequency of the receiver system occurs.
